(19) United States
(12) Patent Application Publication
(10) Pub. No.: US 2016/0314997 A1
(43) Pub. Date: Oct. 27, 2016

(54) LOADLOCK APPARATUS, COOLING PLATE ASSEMBLY, AND ELECTRONIC DEVICE PROCESSING SYSTEMS AND METHODS

(71) Applicant: Applied Materials, Inc., Santa Clara, CA (US)

(72) Inventors: Paul B. Reuter, Austin, TX (US); Travis Morey, Austin, TX (US)

(21) Appl. No.: 14/693,386

(22) Filed: Apr. 22, 2015

(51) Int. Cl. H01L 21/67; H01L 21/687

(52) U.S. Cl. CPC H01L 21/67109; H01L 21/68707

(57) ABSTRACT

A loadlock apparatus including a lower disc diffuser is provided. The loadlock apparatus includes a loadlock body containing a lower loadlock chamber and an upper load loadlock chamber, a lower cooling plate in the lower loadlock chamber, and an upper cooling plate in the upper loadlock chamber. The lower disc diffuser may be centrally located above the lower cooling plate. An upper disc diffuser may be centrally located above the upper cooling plate. Systems including the loadlock apparatus and methods of operating the loadlock apparatus are provided. A cooling plate assembly that is readily removable for cleaning is also provided, as are numerous other aspects.

### FIELD

The present invention relates generally to electronic device manufacturing, and more specifically to loadlock apparatus.

### BACKGROUND

Conventional electronic device manufacturing tools may include multiple process chambers and one or more loadlock chambers surrounding a transfer chamber. These electronic device manufacturing systems may employ a transfer robot that may be housed within the transfer chamber, and which transports substrates between the various process chambers and the one or more loadlock chambers. In some instances, the loadlock chambers may be stacked one on top of the other (e.g., dual loadlocks).

A factory interface, sometimes referred to as an equipment front end module (EFEM), may be provided to load substrates into and out of the one or more loadlock chambers at the front thereof.

Although adequate for their intended purpose, existing loadlock chamber designs suffer from several problems. In such loadlock chambers, cleaning may be undertaken periodically to remove contaminants, residue, and/or particles. However, in existing loadlock chambers, a chamber cleaning the loadlock chambers is time consuming and labor intensive. Further, existing loadlock chambers including a stacked loadlock configuration may suffer from thermal concerns. Accordingly, improved loadlock apparatus, systems, and methods enabling ease of cleaning and/or improved thermal properties are desired.

### SUMMARY

In a first aspect, a loadlock apparatus is provided. The loadlock apparatus includes a loadlock body including a lower loadlock chamber and an upper load loadlock chamber, a lower cooling plate provided in the lower loadlock chamber, an upper cooling plate provided in the upper loadlock chamber, a lower disc diffuser centrally located above the lower cooling plate, and an upper disc diffuser centrally located above the upper cooling plate.

According to another aspect, a cooling plate assembly for a loadlock apparatus is provided. The cooling plate assembly includes a cooling plate including cross-drilled passages, a distribution channel and a collection channel wherein each of the distribution channel and the collection channel intersects the cross-drilled passages, an inflow coupling member and an outflow coupling member coupled to the cooling plate, the inflow coupling member including an entry channel and the outflow coupling member including an exit channel, the entry channel and the exit channels being interconnected to the cross-drilled passages by the distribution channel and the collection channel, a flexible inflow conduit coupled to the inflow coupling member, and a flexible outflow conduit coupled to the outflow coupling member.

According to another aspect, an electronic device processing system is provided. The electronic device processing system includes a mainframe including a robot configured to move substrates, a factory interface having one or more load ports, and a loadlock apparatus received between the mainframe and the factory interface, the loadlock apparatus including: a loadlock body including a lower loadlock chamber and an upper load loadlock chamber, a lower cooling plate provided in the lower loadlock chamber, an upper cooling plate provided in the upper loadlock chamber, a lower disc diffuser centrally located above the lower cooling plate, and an upper disc diffuser centrally located above the upper cooling plate.

In another aspect, a method of processing substrates is provided. The method of processing substrates includes providing a loadlock apparatus located between a mainframe and a factory interface, the loadlock apparatus including a loadlock body including a lower loadlock chamber and an upper load loadlock chamber, a lower cooling plate provided in the lower loadlock chamber, an upper cooling plate provided in the upper loadlock chamber, a lower disc diffuser centrally located above the lower cooling plate, and an upper disc diffuser centrally located above the upper cooling plate, and flowing inert gas through the lower disc diffuser above the lower cooling plate.

Numerous other features are provided in accordance with these and other aspects of the invention. Other features and aspects of the present invention will become more fully apparent from the following detailed description, the appended claims and the accompanying drawings.

### BRIEF DESCRIPTION OF THE DRAWINGS

A person of ordinary skill in the art will understand that the drawings, described below, are for illustrative purposes only. The drawings are not necessarily drawn to scale and are not intended to limit the scope of embodiments of the invention in any way.

FIG. 1 illustrates a schematic top view of a substrate processing system (with a lid of transfer chamber removed) including a loadlock apparatus according to one or more embodiments.

FIG. 2A illustrates a first cross-sectioned side view of a loadlock apparatus according to one or more embodiments.

FIG. 2B illustrates a second cross-sectioned side view of a loadlock apparatus according to one or more embodiments taken perpendicular to the cross-section of FIG. 2A.

FIG. 2C illustrates an enlarged cross-sectioned view of a lower diffuser assembly of a loadlock apparatus according to one or more embodiments.

FIG. 2D illustrates a cross-sectioned upward-looking view of a lower diffuser assembly of a loadlock apparatus according to one or more embodiments.

FIG. 2E illustrates a cross-sectioned downward-looking view of a cutout formed in the loadlock body of a loadlock apparatus with the cooling plate assembly removed according to one or more embodiments.

FIGS. 3A-3B illustrates various top views of an upper lift assembly of a loadlock apparatus according to one or more embodiments.

FIG. 4A illustrates an underside perspective view of an upper cooling plate assembly of a loadlock apparatus according to one or more embodiments.

FIG. 4B illustrates an top perspective view of an upper cooling plate assembly of a loadlock apparatus according to one or more embodiments.

FIG. 4C illustrates a cross-sectioned top view of an upper cooling plate according to one or more embodiments.

FIG. 4D illustrates a cross-sectioned top view of a lower cooling plate according to one or more embodiments.

FIG. 4E illustrates a cross-sectioned side view of an upper cooling plate assembly installed onto a loadlock body according to one or more embodiments.

FIG. 4F illustrates an enlarged cross-sectioned side view of a portion of an upper cooling plate assembly according to one or more embodiments.

FIG. 5 illustrates a flowchart depicting a method of processing substrates in a loadlock apparatus according to one or more embodiments.

### DESCRIPTION

In substrate processing, sometimes a loadlock chamber is used to actively cool substrates that are exiting process chambers coupled to the transfer chamber where the substrate is exposed to heat. The substrates are passed into a loadlock chamber, undergo cooling, and then are further transferred through the factory interface via an factory interface robot. In instances where stacked loadlock chambers are used, which is desirable for large throughput, existing loadlock chamber designs may not provide a suitable thermal environment for both the upper and lower loadlock chambers. This can result in uneven cooling between substrates exiting the top or the bottom or perhaps different cycle times, both of which are undesirable.

Thus, in a first embodiment, an improved loadlock apparatus including stacked load-lock chambers is provided. The loadlock apparatus includes a loadlock body including a lower loadlock chamber and an upper load loadlock chamber, a lower cooling plate provided in the lower loadlock chamber, an upper cooling plate provided in the upper loadlock chamber, a lower disc diffuser centrally located above the lower cooling plate, and an upper disc diffuser centrally located above the upper cooling plate.

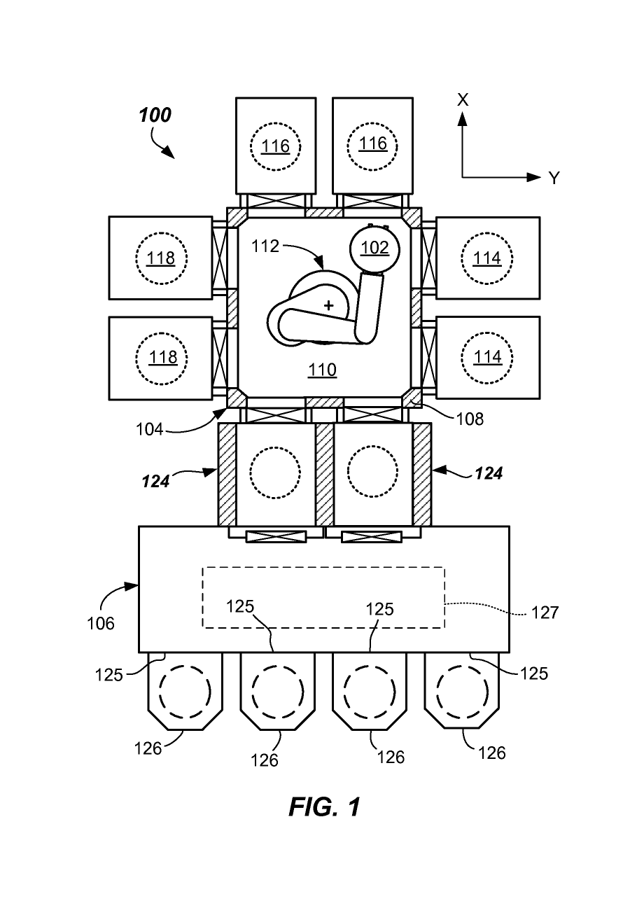

Further details of examples of various embodiments of the invention are described with reference to FIGS. 1-5 herein.

Referring now to FIG. 1, an example of an electronic device processing system 100 according to embodiments of the present invention is disclosed. The electronic device processing system 100 is useful to carry out one or more processes on a substrate 102. The substrate 102 may be a silicon wafer, which may be an electronic device precursor such as an incomplete semiconductor wafer having a plurality of incomplete chips formed thereon. In some cases, the substrate 102 may have a mask thereon.

In the depicted embodiment, the electronic device processing system 100 includes a mainframe 104 provided adjacent to a factory interface 106. The mainframe 104 includes a housing 108 and includes a transfer chamber 110 therein. The housing 108 may include a number of vertical side walls, which may define chamber facets. In the depicted embodiment, the housing 108 includes twined chamber facets, wherein the facets on each side wall are substantially parallel, and the entry directions into the respective twinned chambers that are coupled to the facets are substantially co-parallel. However, as should be appreciated, the line of entry into the respective chambers is not through a shoulder axis of the transfer robot 112. The transfer chamber 110 is defined by the side walls thereof, as well as top and bottom walls and may be maintained at a vacuum, for example. The vacuum level for the transfer chamber 110 may be between about 0.01 Torr and about 80 Torr, for example. Other vacuum levels may be used.

The transfer robot 112 is received in the transfer chamber 110 and includes multiple arms and one or more end effectors that are configured and operable to transport substrates 102 (e.g., the “substrates” and placement locations for substrates are shown in FIG. 1 as circles). The transfer robot 112 may be adapted to pick or place substrates 102 to or from a destination. The destination may be any chamber that is physically coupled to the transfer chamber 110.

For example, the destination may be one or more first process chambers 114 coupled to one or more facets of the housing 108 and accessible from the transfer chamber 110, one or more second process chambers 116 coupled to the housing 108 and accessible from the transfer chamber 110, or one or more third process chambers 118 coupled to the housing 108 and accessible from the transfer chamber 110. A same or different process may take place in each of the first, second, and third process chambers 114, 116, 118.

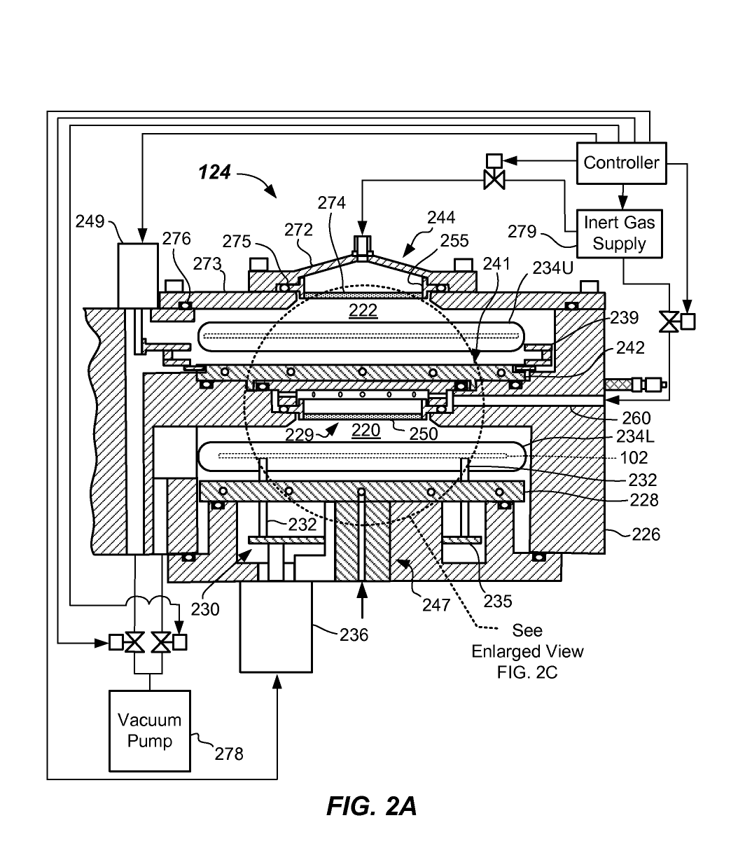

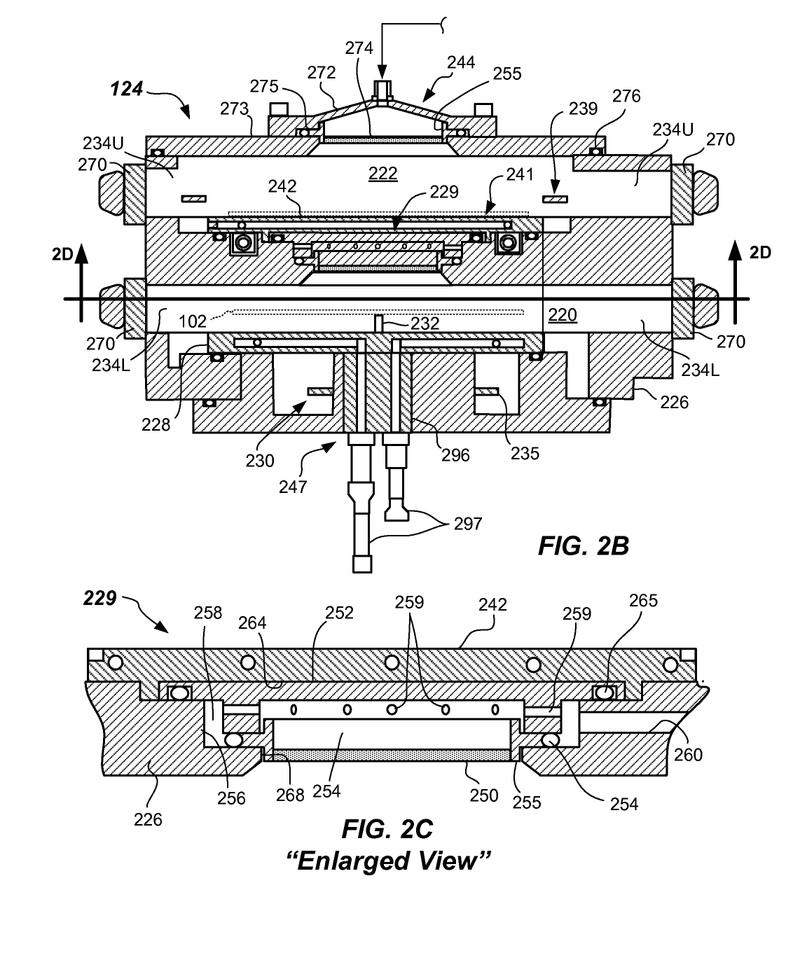

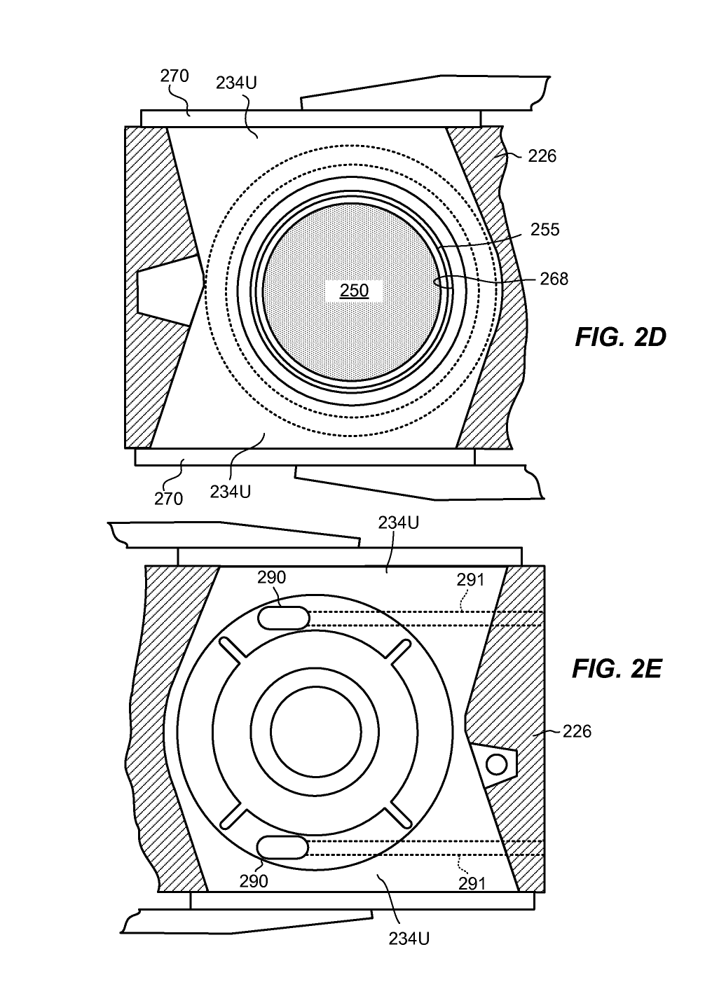

The destination may also be lower loadlock chambers 220 and upper loadlock chamber 222 (e.g., stacked loadlock chambers—see FIGS. 2A-2B) of one or more loadlock apparatus 124 in accordance with one or more embodiments of the present invention. The destinations are shown as dotted circles.

The loadlock apparatus 124 is adapted to interface with the factory interface 106 on one side and may receive substrates 102 removed from substrate carriers 126 (e.g., Front Opening Unified Pods (FOUPs)) docked at various load ports 125 of the factory interface 106. A factory interface robot 127 (shown as dotted) may be used to transfer substrates 102 between the substrate carriers 126 and the loadlock apparatus 124. Any conventional robot type may be used for the factory interface robot 127. Transfers may be carried out in any order or direction. Any robot type capable of servicing twinned chambers may be used for the transfer robot 112.

As shown in FIG. 1, one or more conventional slit valves may be provided at the entrance to each process chamber 114, 116, and 118. Likewise, the loadlock apparatus 124 may include a first slit valve on a first side adjacent to the factory interface 106, and a second slit valve on a second side adjacent to the transfer chamber 110. Separate slit valves maybe provided for the upper loadlock chambers 222 and lower loadlock chambers 220 (FIG. 2B).

In more detail, the loadlock apparatus 124 according to one or more embodiments of the invention will now be described. Loadlock apparatus 124 may be located between, coupled to, and accessed from the both the mainframe 104 and the factory interface 106. As shown in FIGS. 2A-2B, the lower loadlock chamber 220 and upper loadlock chamber 222 are coupled to the housing 108 on one side and to the factory interface 106 on the other. Each loadlock apparatus 124 includes lower loadlock chamber 220 and upper loadlock chamber 222 that are located at different vertical levels (e.g., one above another). Loadlock chambers 220, 222 are configured and adapted to carry out cooling of the substrate 102 post processing in one aspect, and accomplish handoff between the factory interface and the transfer chamber 110 in another aspect, as will be apparent from the following.

The loadlock apparatus 124 is capable of cooling the substrates 102 exiting from one or more of the process chambers 114, 116, 118 from above 300° C. (e.g., about 380° C.) to less than 100° C. (e.g., less than about 80° C.). Cooling of each substrate 102 is adapted to take place in a time frame of less than about 40 seconds.

The processes carried out in process chambers 114, 116, 118 may be any heat generating process, such as deposition, oxidation, nitration, etching, cleaning, lithography, or the like. Other processes may be carried out there, as well.

In one or more embodiments, the process carried out in a process chamber 114, 116, 118 of the loadlock apparatus 124 may be a TiN deposition process. However, the loadlock apparatus 124 may be beneficial for use with any electronic device manufacturing system where the involved process includes substrate heating, followed by rapid cooling. These and other aspects and embodiments are detailed below.

FIGS. 2A-2E illustrates details of a representative example of a loadlock apparatus 124 according to one or more embodiments. Loadlock apparatus 124 includes a loadlock body 226 of rigid material (e.g., aluminum) that may be connectable to the factory interface 106 on a first side and to the housing 108 of the mainframe 104 on an opposite side. Connection may be directly or through an intermediate member, such as a spacer. Connection may further be by mechanical connection, such as by bolting or the like. One or both of the connection interfaces with the factory interface 106 and the housing 108 may be sealed in some embodiments. The loadlock body 226 may be one integral piece of material in some embodiments, or may be constituted of multiple connected pieces in others.

The loadlock apparatus 124 includes a lower loadlock chamber 220 and an upper loadlock chamber 222 located above the lower loadlock chamber 220. Each of the upper loadlock chamber 222 and lower loadlock chamber 220 may be accessible from the transfer chamber 110 and also from the factory interface 106.

Upper loadlock chamber 222 and lower loadlock chamber 220 each include upper openings 234U and lower openings 234L, each having a respective slit valve acting to open and close access thereto. Accordingly, substrates 102 may pass through the lower loadlock chamber 220 and upper loadlock chamber 222 in either direction. Slit valves may include any suitable slit valve construction, such as taught in U.S. Pat. Nos. 6,173,938; 6,347,918; and 7,007,919. In some embodiments, the slit valves may be L-motion slit valves, for example.

The loadlock apparatus 124 may include associated with the lower loadlock chamber 220, a lower cooling plate 228, a lower diffuser assembly 229, and a lower lift assembly 230.

The lower lift assembly 230 may include supports 232, such as lift pins (e.g., three lift pins), passing through the lower cooling plate 228 and that are adapted to allow one or more substrates 102 (shown dotted) to be placed and removed by transfer robot 112 and factory interface robot 127 (FIG. 1), i.e., allowed to pass through. Supports 232 may be coupled to a lift member 235, which may be actuated up and down by a lift motor 236. Substrates 102 placed on the supports 232 are accessible by the transfer robot 112 and the factory interface robot 127 by extending the end effectors through the respective openings 234L into the lower loadlock chamber 220.

Handoff of substrates 102 into the transfer chamber 110 may be handled with the supports 232 in the up position, where no cooling is wanted. During handoff following processing at one or more of the process chambers 114, 116, 118, when the substrate 102 is hot (e.g., >300° C.), the substrate 102 is first placed on the supports 232, the slit valve door 270 closed, then the supports 232 are lowered to lower the substrate 102 into thermal contact with the lower cooling plate 228.

Thermal contact may be through intimate contact or near field contact where near field conduction may take place. Near field conduction may be accomplished by using numerous (e.g. numbering from about 10 to 40) small spacers that keep the substrate 102 spaced (e.g., by less than about 0.02 inch) from an upper surface of the lower cooling plate 228. Once the slit valve doors 270 are closed, an inert gas (e.g., N₂) may be flowed into the lower diffuser assembly 229 and the lower loadlock chamber 220 may be brought back to about atmospheric pressure so that heat transfer may take place efficiently, and the substrate 102 may begin the cooling process.

The lower loadlock chamber 220 may include a vacuum pump 278 connected thereto. Vacuum pump 278 may be shared between the upper and lower loadlock chambers, albeit it is desired that a pressure of each may be drawn down separately at different times. Thus, loadlock chambers 220, 222 may be undergoing pass through or optionally pass through with cooling at different times.

### Lower Diffuser Assembly

The lower diffuser assembly 229 may include, as best shown in FIG. 2A and enlarged view FIG. 2C, a lower disc diffuser 250 that is circular (disc shaped) and centrally located above the lower cooling plate 228. For example, a central axial axis the lower disc diffuser 250 may substantially coincide with a central axial axis the lower cooling plate 228 so that the lower disc diffuser 250 is positioned centrally and directly vertically above the substrate 102 as positioned on the supports 232 or on the lower cooling plate 228. The lower disc diffuser 250 may have an outer diameter of between about 50 mm and 250 mm. The lower disc diffuser 250 may be a porous metal material such as sintered metal (e.g., stainless steel or nickel or alloys thereof), for example. Lower disc diffuser 250 may have an open interconnected porosity and may have a particle collection efficiency of about 99.9% at 0.2 μm particle size per IBR E304, and may have a particle collection efficiency of greater about 90% for all particle sizes. Thus, the lower disc diffuser 250 functions to diffuse flow into the lower loadlock chamber 220, but may also function as a particle filter. Other suitable sizes, porosities and porous microstructures may be used. Use of the lower disc diffuser 250 may reduce redistribution of particles onto the substrate 102 and may prevent introduction of new particles from the inert gas supply 279. Centrally locating the lower disc diffuser 250 above the lower cooling plate 228 and substrate 102 thereon may provide a benefit of reduced on-substrate particles. An additional benefit of embodiments of the invention including a centrally located upper and lower disc diffusers 250, 274 in both the upper and lower loadlock chambers 220, 220 is that all substrates 102 passing through the upper or lower loadlock chambers 220, 222 will undergo approximately same conditions. Embodiments of the present invention loadlock apparatus 124 include chamber designs of the upper and lower loadlock chambers 220, 222 wherein the process gas flow may be substantially the same between the upper and lower loadlock chambers 220, 222. The centrally located disc diffusers 250, 274 in embodiments of the invention are integrated into both the upper and lower loadlock chambers.

The lower diffuser assembly 229 may include a diffuser housing 252 mounted to the loadlock body 226, a diffuser cavity 254 formed at least in part by walls of the diffuser housing 252 and the lower disc diffuser 250. In one or more embodiments, the lower disc diffuser 250 may be mounted to a diffuser frame 255, and portions of the diffuser frame 255 may help define the diffuser cavity 254.

The lower diffuser assembly 229 may be mounted into a recess 256 formed in the loadlock body 226 and together, the recess 256 and the lower diffuser assembly 229 form a channel 258, such as an annulus. The channel 258 is formed between the walls of the recess 256 and the outer portion of the lower diffuser assembly 229. The lower diffuser assembly 229 may include a plurality of holes 259 passing through the walls of the diffuser housing 252, for example, and connecting between the channel 258 (e.g., annulus) and the diffuser cavity 254.

Thus, in operation, inert gas from an inert gas supply 279 (FIG. 2A) may be provided to the channel 258 through a gas passageway 260 that may be formed generally horizontally in the loadlock body 226 between the lower loadlock chamber 220 and the upper loadlock chamber 222. The inert gas traverses about the channel 258 and flows in through the plurality of holes 259 into the diffuser cavity 254. The number of holes 259 may between about 6 and 18, for example. The diameter of the holes 259 may be between about 2 mm and 6 mm, for example. The holes 259 may be round, oblong, slots, or the like. Other numbers, sizes, and shapes of holes 259 may be used. Holes 259 may be designed to provide uniform flow into the diffuser cavity 254. The inert gas flowing into the diffuser cavity 254 under pressure then diffuses through the porous wall of the lower disc diffuser 250 and then into the lower loadlock chamber 220.

In one or more embodiments, an upper portion of the diffuser housing 252 may be received in a pocket 264 formed in a bottom portion of the upper cooling plate 242. This may function to register the location of the lower disc diffuser 250. As shown, the upper cooling plate 242 may include a registration feature that locates the upper cooling plate 242 relative to the loadlock body 226. Upper cooling plate 242 may be fastened to the loadlock body 226 by fasteners (not shown) and may be sealed to the loadlock body 226 with a seal (e.g., an O-ring). A flange of the diffuser housing 252 may be sealed against an upper surface of the loadlock body 226 such as by a first seal 265 (e.g., O-ring seal) and the operation of securing the upper cooling plate 242 to the loadlock body 226 or by being separately fastened to the loadlock body 226. Fastening may be by bolts, screws, or the like.

In the depicted embodiment, the diffuser frame 255 and the lower disc diffuser 250 are registered by being received in an opening 268 in the loadlock body 226, sealed by a second seal (e.g., an O-ring), and secured in place by securing the upper cooling plate to the loadlock body 226 or by securing the diffuser housing 252 to the loadlock body 226. The lower disc diffuser 250 may be welded or otherwise secured to the diffuser frame 255.

### Upper Loadlock Chamber

The loadlock apparatus 124 may also include an upper loadlock chamber 222. Upper loadlock chamber 222 is located at a different vertical level than the lower loadlock chamber 220 (e.g., directly above). Upper loadlock chamber 222, like lower loadlock chamber 220, is adapted to allow for the passing through of substrates 102 and/or passing through of substrates 102 with augmented cooling. In this manner, additional throughput and cooling capability for the particular tool is provided in the loadlock apparatus 124.

Because the upper and lower loadlock chambers 220, 222 are at different heights, Z-axis capability may be provided in the transfer robot 112 and factory interface robot 127. Vertical Z-axis capability of up to about 90 mm may be provided by the transfer robot 112 and the factory interface robot 127 in some embodiments. A center-to-center vertical spacing between the upper loadlock chamber 222 and the lower loadlock chamber 220 may be about 80 mm. Other vertical spacing dimensions may be used.

Process chambers 114, 116, 118 may be located at a same vertical level as the lower loadlock chamber 220, same vertical level as the upper loadlock chamber 222, or at a level in between, for example. Other process chamber locations may be used.

As shown in FIG. 2B, entry of substrates 102 in the depicted embodiment is through an upper openings 234U and lower openings 234L communicating with the transfer chamber 110 and the factory interface 106. In the depicted embodiment, slit valve doors 270 may seal the upper openings 234U and lower openings 234L of the upper loadlock chamber 222 and lower loadlock chambers 220, respectively. The slit valve door 270 may be actuated by any suitable type of slit valve mechanism discussed above.

Now referring to both FIGS. 2A and 2B, the upper loadlock chamber 222 may include an upper lift assembly 239 operable therewith. A substrate 102 may rest upon the upper lift assembly 239 at times, and on an upper cooling plate assembly 241 including an upper cooling plate 242 at other times (e.g., when augmented cooling is desired). Loadlock apparatus 124 may also include an upper diffuser assembly 244 associated with the upper loadlock chamber 222.

### Upper Lift Assembly

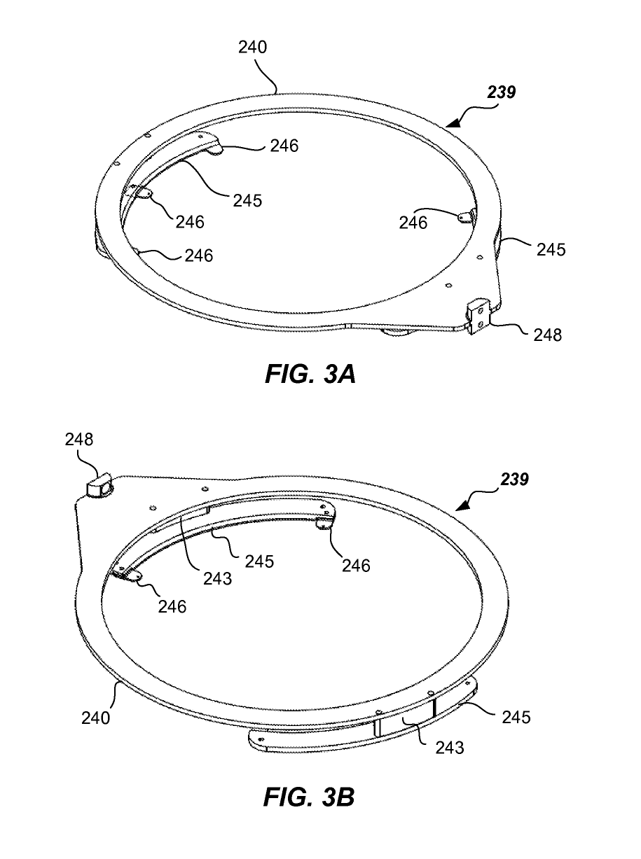

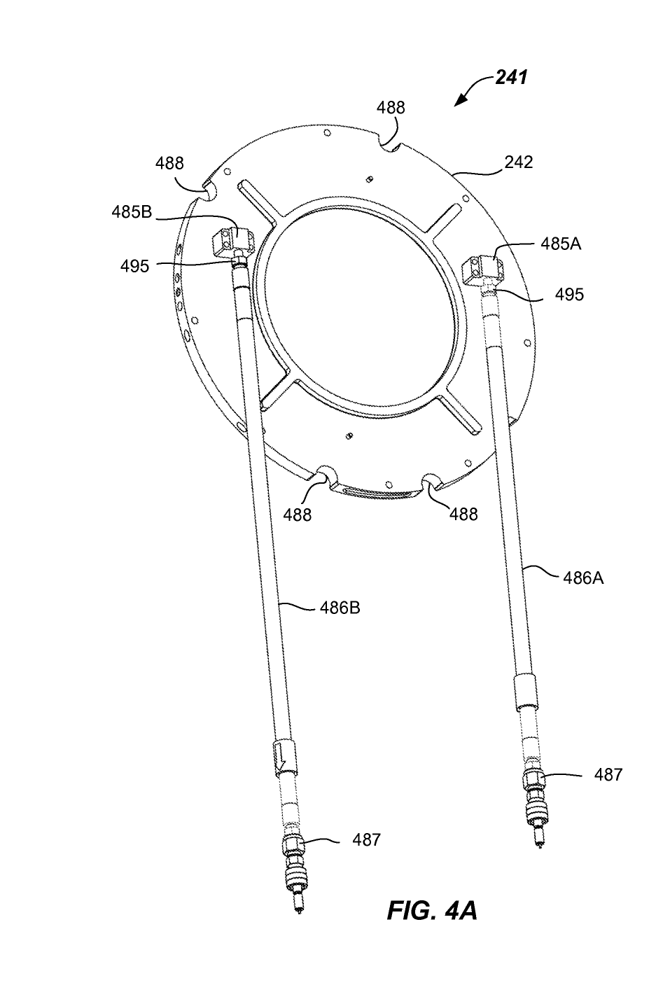

A portion of the upper lift assembly 239 may be constructed as shown in FIGS. 3A and 3B. Upper lift assembly 239 may include a ring 240, and segments 245 coupled below the ring 240, such as by spacers 243 shown. Each segment 245 may be spaced across the ring 240 and may include one or more upper supports 246, which may be finger tabs, thereon. Some or all of the upper supports 246 are configured and adapted to contact substrate 102 as the substrate 102 is lowered onto the upper cooling plate 242 for cooling in the upper loadlock chamber 222, or for a pass through operation of the substrate 102 (passing between the factory interface 106 to the transfer chamber 110). In the depicted embodiment two or more upper supports 246 are provided on each segment 245. More or less numbers of upper supports 246 may be used, provided that a three-point contact is provided across the upper lift assembly 239. The upper lift assembly 239 may include a lift actuator 249 (FIG. 2A) adapted to couple to a lift connector 248 formed on the ring 240, such as by bolts, screws or the like.

### Upper Diffuser Assembly

In more detail, the upper diffuser assembly 244 as shown in FIG. 2A-2B may include an upper diffuser housing 272 coupled to a chamber lid 273, such as by fasteners (e.g., bolts, screws, or the like). An upper disc diffuser 274 may be provided as part of the upper diffuser assembly 244 and may be identical in construction as the lower disc diffuser 250 described herein. Upper disc diffuser 274 may be mounted in a diffuser frame 255 in the same manner as the lower disc diffuser 250. The upper diffuser assembly 244 may be sealed to the chamber lid 273 by third seal 275 (e.g., an O-ring seal). Likewise, chamber lid 273 may be sealed to the loadlock body 226 by fourth seal 276 (e.g., an O-ring seal).

A vacuum level in the upper loadlock chamber 222 and the lower loadlock chamber 220 may be controlled. For example, in some embodiments, the upper loadlock chamber 222 and the lower loadlock chamber 220 may be evacuated by a coupled vacuum pump 278 to a suitable vacuum level. For example, the vacuum level may be provided at a pressure of range of between about 0.01 Torr to about 80 Torr. Other vacuum pressures may be used. It should be recognized that the vacuum pump 278 may be connected to both the upper loadlock chamber 222, and the lower loadlock chamber 220. Given that the upper and lower loadlock chambers 222, 220 may be operated at different cycle times (e.g., alternating between upper and lower loadlock chambers 222, 220), the vacuum pump 278 may be shared between the upper and lower loadlock chambers 222, 220. Vacuum pump 278 and control valves (FIG. 2A) may be provided underneath the loadlock body 226 and may be used to generate a suitable vacuum within the upper and lower loadlock chambers 222, 220. Control valves may be KF-40 type gate valves, or the like. Vacuum pump 278 may be a BOC Edwards pump, or the like. Other suitable control valves and vacuum pumps may be used.

Additionally, as discussed above, an inert gas (e.g., N₂) may be supplied to the upper and lower loadlock chambers 222, 220 to bring the pressure level back to near atmospheric pressure, and to ensure that the substrates 102 are not exposed to any appreciable amounts of oxygen or moisture. For example, inert gases such as nitrogen (N₂) or even argon (Ar), or helium (He) may be introduced from the inert gas supply 279. Combinations of inert gases may be supplied.

Again referring to FIG. 1, electronic device processing system 100 may include more than one loadlock apparatus 124, arranged in a side-by-side arrangement as shown. The two loadlock apparatus 124 may be identical to each other. In some embodiments, the two loadlock apparatus 124 may share a loadlock body 226 (see FIG. 2A) that is common to both.

In one or more embodiments, a slit valve assembly including the slit valve doors 270 may be wide enough to simultaneously seal the loadlock apparatus 124 even when arranged in side-by-side relationship.

### Upper Cooling Plate Assembly

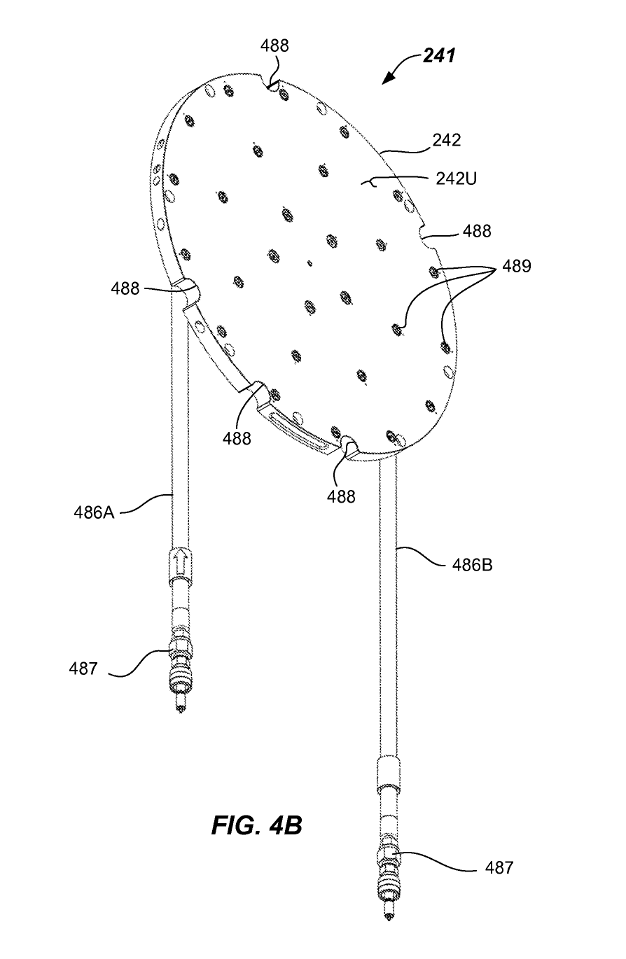

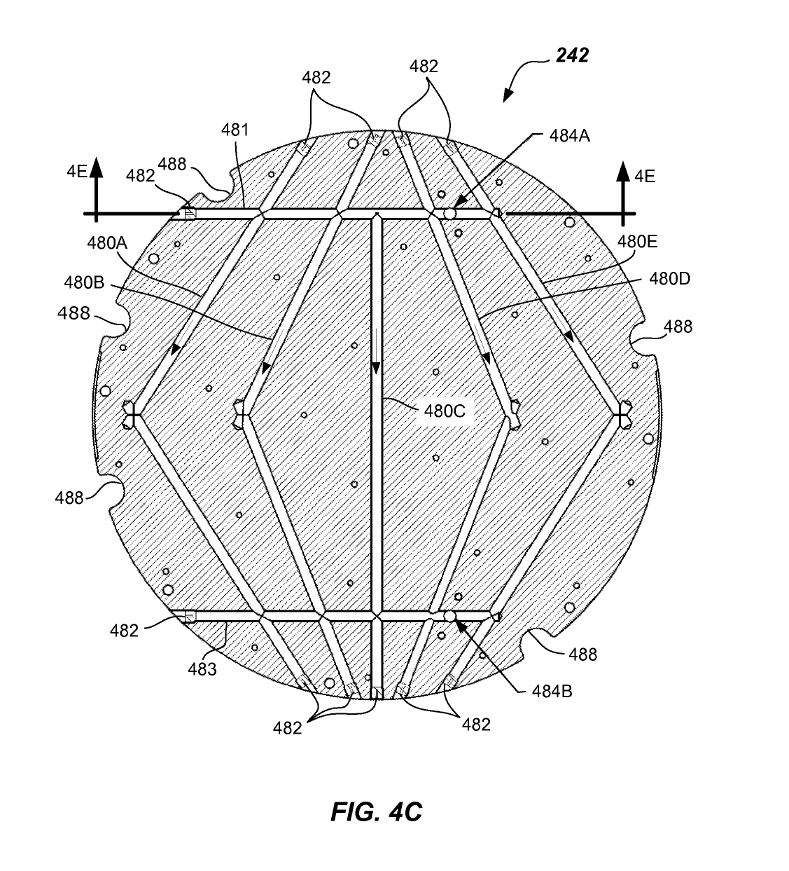

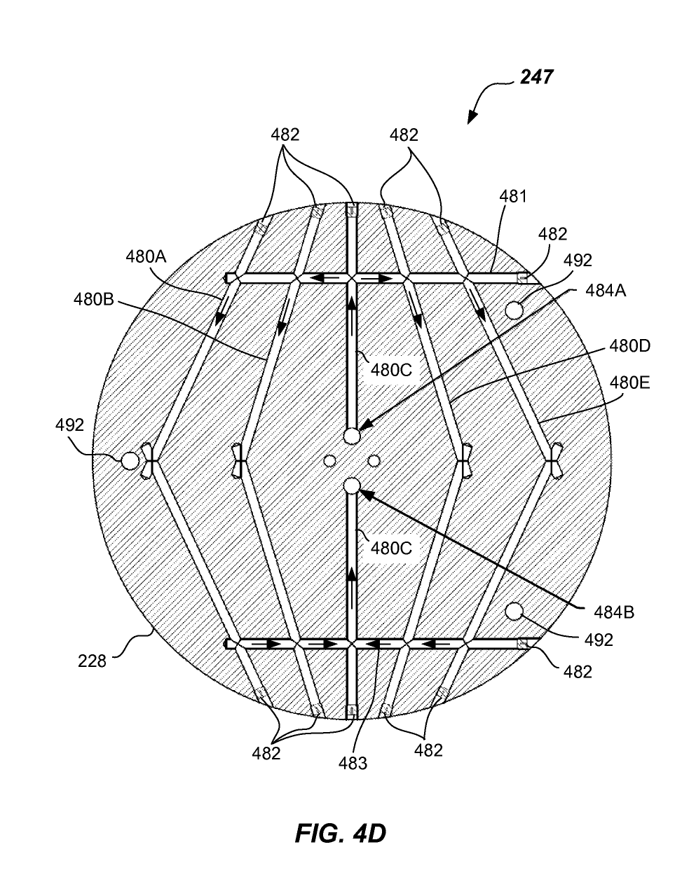

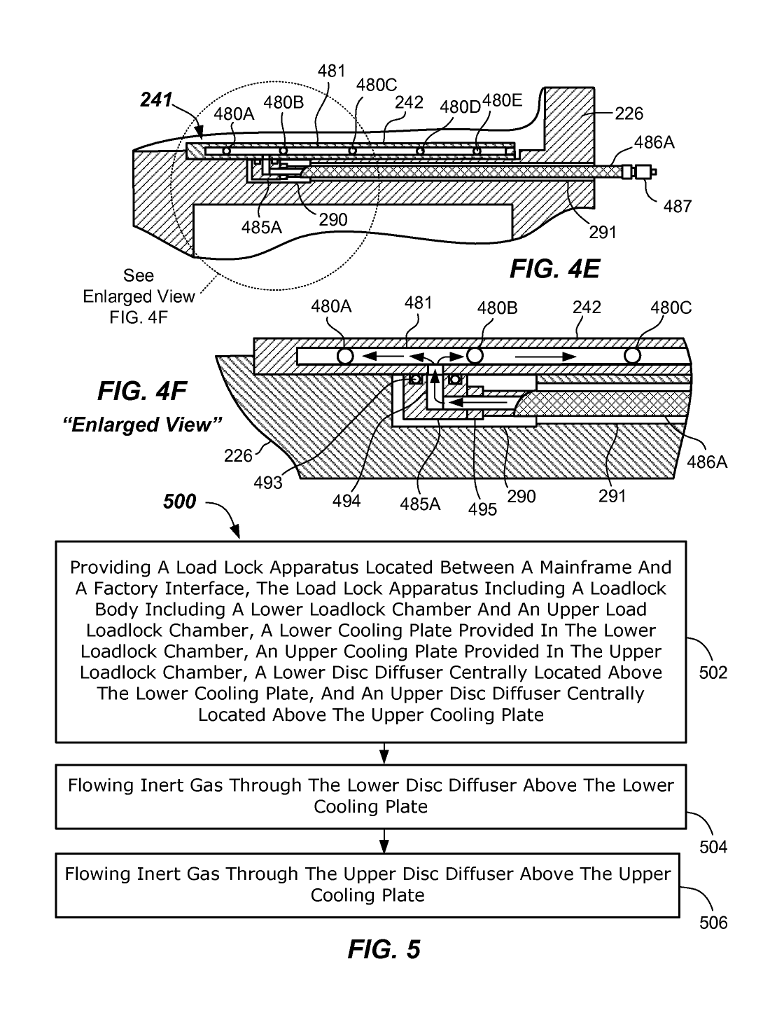

Referring now to FIG. 2E and FIGS. 4A-4C and 4E, the upper cooling plate assembly 241 will be described in detail. The upper cooling plate assembly 241 may include an upper cooling plate 242, which may be made of a thermally-conductive material (e.g., aluminum or aluminum alloy material) adapted to be provided in thermal contact with a substrate 102. The upper cooling plate 242 may include a plurality of passages 480A-480E formed therein, as shown in FIGS. 4C and 4E, a distribution channel 481, and a collection channel 483.

Some of the plurality of passages 480A-480E, the distribution channel 481, and collection channel 483 may be cross-drilled passages, which may then be plugged with plugs 482 to close the ends of the passages 480A-480E, the distribution channel 481, and collection channel 483. “Cross-drilled passage” as used herein means a passage that is machined (e.g., drilled, drilled and reamed, or otherwise machined) across a lateral extent of the upper cooling plate 242, generally parallel to an upper surface 242U (FIG. 4B) of the upper cooling plate 242. Plugs 482 may be threaded plugs 482 and may be received, and sealed in, threaded end portions of the plurality of passages 480A-480E, distribution channel 481, and collection channel 483. Any suitable thread sealant may be used. Other types of plugs may be used.

As shown in FIG. 4C, passages 480A, 480B, 480D, and 480E may be formed as intersecting straight holes that are cross-drilled from opposite lateral sides of the upper cooling plate 242 and that may intersect each other near the center of the upper cooling plate 242, for example. The passages 480A, 480B, 480D, and 480E may be divergent from each other and from central passage 480C, as machined, in some embodiments. The central passage 480C may be machined (e.g., drilled) from one lateral side only. The passages 480A-480E, distribution channel 481, and collection channel 483 may be between about 6 mm to about 12 mm in diameter, for example. Other sizes may be used. The diameter of the upper cooling plate 242 may be sufficiently large to accommodate substrates 102 having a diameter of about 300 mm about 450 mm, for example. Other substrate sizes may be accommodated.

As shown in FIG. 4C, distribution channel 481 and collection channel 483 may be cross-drilled and may intersect passages 480A-480E. The intersection allows cooling liquid distribution and cooling liquid flow (see arrows). Cooling liquid flow enters at an entrance 484A, is distributed by distribution channel 481, passes into the passages 480A-480E providing active cooling of the upper cooling plate 242, collected by the collection channel 483, and then exits at exit 484B.

The entrance 484A and exit 484B may be coupled to, and fluidly interconnect with, inflow coupling member 485A and outflow coupling member 485B, respectively. Thus, inflow coupling member 485A receives fluid (e.g., cooling liquid) and outflow coupling member 485B expels fluid (e.g., cooling liquid) from the upper cooling plate 242.

As shown in enlarged view of FIG. 4E, inflow coupling member 485A and outflow coupling member 485B may be fastened to an underside of the upper cooling plate 242, such as by screws or bolts, or may be integral therewith in some embodiments. Inflow coupling member 485A and outflow coupling member 485B may be sealed to an underside of the upper cooling plate 242, such as with an O-ring 493, in some embodiments. Inflow coupling member 485A and outflow coupling member 485B may be identical.

Flexible inflow conduits 486A and flexible outflow conduit 486B may be coupled to the inflow coupling member 485A and outflow coupling member 485B, respectively, and may be a configured to carry the cooling liquid to and from the inflow coupling member 485A, and outflow coupling member 485B, respectively, and function as a coolant inflow (e.g., flexible inflow conduit 486A) and a coolant outflow (e.g., flexible outflow conduit 486B). Flexible inflow conduit 486A and flexible outflow conduit 486B may be stainless steel braided hoses having an inner diameter of between about 6 mm and 13 mm and a length of between about 40 cm and 65 cm. Other sizes and hose types may be used.

The flexible inflow conduit 486A and flexible outflow conduit 486B may include connectors 487, which may be quick-disconnect couplings in some embodiments, that couple to a source of cooling liquid (not shown). The flexible inflow conduit 486A and flexible outflow conduit 486B may have a length sufficient to pass through the passageways 291 and place the connectors 487 at a location that is spaced from the loadlock body 226, where the connectors 487 can be easily accessed and connected (See FIGS. 2A and 4E).

As shown in enlarged FIG. 4F, the upper cooling plate assembly 241 for the loadlock apparatus 124 includes the inflow coupling member 485A coupled to and sealed to the upper cooling plate 242, wherein the inflow coupling member 485A includes an entry channel 494 and the outflow coupling member 485B includes an exit channel (identical to the entry channel 494). The entry channel 494 and the exit channel may be interconnected to the cross-drilled passages 480A-480E by the distribution channel 481 and the collection channel 483. As shown, the flexible inflow conduit 486A is coupled to the inflow coupling member 485A, and the flexible outflow conduit 486B may be coupled to the outflow coupling member 485B, such as by hose connectors 495.

Shown in the upper cooling plate 242 (FIGS. 4A-4C) are multiple edge recesses 488 that are configured and adapted to receive upper supports 246 (FIGS. 3A, 3B) below the upper surface 242U thereof. The upper supports 246 of the upper lift assembly 239 (FIGS. 3A and 3B) are adapted to contact, lift, or lower the substrate 102 at times during handoff and/or cooling. The upper surface 242U may include multiple contacts 489 located thereon. Contacts 489 may be positioned to space the substrate 102 very close to the upper surface 242U yet be in near-flied thermal contact therewith as discussed above.

After installation of the lower diffuser assembly 229 onto the loadlock body 226, the upper cooling plate assembly 241 may be assembled to the loadlock body 226. To receive the upper cooling plate assembly 241, as best shown in FIGS. 2E and 4D, 4E, and 4F, the loadlock body 226 includes two cutouts 290 in a floor of the loadlock body 226 that are intersected by and couple to passageways 291. The cutouts 290 may be about 140 mm long, 35 mm wide and about 22 mm deep. Other sizes and shapes may be used. The cutouts 290 receive the inflow coupling member 485A, and outflow coupling member 485B and the passageways 291 (shown dotted in FIG. 2E) are configured to receive the flexible inflow conduit 486A and flexible outflow conduit 486B therein. Passageways 291 may be of sufficient diameter to allow the connectors 487 to pass there through generally unimpeded.

To install the upper cooling plate assembly 241 to the loadlock body 226, the connectors 487 are fed into the cutouts 290 and then into the passageways 291 formed generally horizontally in the loadlock body 226. The upper cooling plate assembly 241 may then be fastened in place, such as by screws or bolts. Following this, the upper lift assembly 239 and chamber lid 273 may be installed and secured. To remove the upper cooling plate assembly 241 for cleaning, the reverse of the above may be undertaken. The unique construction of the upper cooling plate assembly 241 allows for ease of removal for cleaning and ease of connection/disconnection from the loadlock apparatus 124. The cross-drilled and plugged passages of the upper cooling plate 242 allow for a single piece construction of the body of the upper cooling plate 242.

### Lower Cooling Plate Assembly

FIGS. 2A, 2B, and 4D illustrate an example embodiment of a lower cooling plate assembly 247. Lower cooling plate assembly 247 includes the lower cooling plate 228, and lower plate extension 296 coupled thereto. As shown in FIG. 4D, the lower cooling plate 228 may include cross-drilled passages 480A-480E that may be end plugged with plugs 482. In this embodiment, the entrance 484A and exit 484B may be centrally located. Like the previous embodiment, the distribution channel 481 receives and distributes fluid flow to the cross-drilled passages 480A-480E, and the collection channel 483 collects fluid flow from the cross-drilled passages 480A-480E. Fluid flow enters and exits through plate extension 296. Fluid couplings 297 (FIG. 2B) may be coupled to the plate extension 296, which may couple to a fluid source (not shown). Apertures 492 may be formed therein to accept supports 232 there through (lift pins of FIG. 2A).

As shown in FIG. 5, a method 500 of processing substrates (e.g., substrates 102) is provided. The method 500 includes, in 502, providing a loadlock apparatus (e.g., loadlock apparatus 124) located between a mainframe (e.g., loadlock apparatus 124) and a factory interface (e.g., factory interface 106), the loadlock apparatus including a loadlock body (e.g., loadlock body 226) including a lower loadlock chamber (e.g., lower loadlock chamber 220) and an upper loadlock chamber (e.g., upper loadlock chamber 222), a lower cooling plate (e.g., lower cooling plate 228) provided in the lower loadlock chamber, an upper cooling plate (e.g., upper cooling plate 242) provided in the upper loadlock chamber, a lower disc diffuser (e.g., lower disc diffuser 250) centrally located above the lower cooling plate, and an upper disc diffuser (e.g., upper disc diffuser 274) centrally located above the upper cooling plate.

The method 500 includes, in 504, flowing inert gas through the lower disc diffuser above the lower cooling plate. The method 500 may also include, in 506, flowing inert gas through the upper disc diffuser (e.g., upper disc diffuser 274) above the upper cooling plate (e.g., upper cooling plate 242).

The foregoing description discloses only exemplary embodiments of the invention. Modifications of the above-disclosed systems, apparatus and methods which fall within the scope of the invention will be readily apparent to those of ordinary skill in the art. Accordingly, while the present invention has been disclosed in connection with exemplary embodiments thereof, it should be understood that other embodiments may fall within the scope of the invention, as defined by the following claims.

The invention claimed is:

1. A loadlock apparatus, comprising:
a loadlock body including a lower loadlock chamber and an upper load loadlock chamber;
a lower cooling plate provided in the lower loadlock chamber;
an upper cooling plate provided in the upper loadlock chamber;
a lower disc diffuser centrally located above the lower cooling plate; and
an upper disc diffuser centrally located above the upper cooling plate.

2. The loadlock apparatus of claim 1, comprising a lower diffuser assembly including the lower disc diffuser, the lower diffuser assembly including a diffuser housing mounted to the loadlock body, a diffuser cavity formed at least in part by walls of the diffuser housing and the lower disc diffuser.

3. The loadlock apparatus of claim 1, comprising a lower diffuser assembly including a diffuser housing, a diffuser cavity formed at least in part by walls of the diffuser housing and the lower disc diffuser, and a plurality of holes passing through the walls.

4. The loadlock apparatus of claim 1, comprising a recess formed in the loadlock body, a lower diffuser assembly including a diffuser housing mounted to the loadlock body and forming a channel between an outer portion of the lower diffuser assembly and the recess, a diffuser cavity formed at least in part by inner walls of the diffuser housing and the lower disc diffuser, and a plurality of holes passing through the walls and connecting the channel and the diffuser cavity.

5. The loadlock apparatus of claim 4, comprising a passageway in the loadlock body connecting with the channel.

6. The loadlock apparatus of claim 4, wherein an upper portion of the diffuser housing is received in a pocket formed in the upper cooling plate.

7. The loadlock apparatus of claim 4, wherein a flange of the diffuser housing is sealed against the loadlock body.

8. The loadlock apparatus of claim 1, wherein the loadlock body comprises pockets and passageways coupled to the pockets, wherein the pockets received an inflow coupling member and an outflow coupling member, and passageways receive flexible conduits of an upper cooling plate assembly including the upper cooling plate.

9. The loadlock apparatus of claim 1, wherein the loadlock body comprises two pockets formed in a floor of the loadlock body and a passageway intersecting each of the pockets and passing horizontally in the loadlock body, wherein the pockets are adapted to receive inflow coupling member and an outflow coupling member and the passageways are adapted to receive flexible conduits.

10. The loadlock apparatus of claim 1, wherein the lower cooling plate comprises cross-drilled passages that are plugged.

11. The loadlock apparatus of claim 1, wherein the upper cooling plate comprises cross-drilled passages that are plugged.

12. The loadlock apparatus of claim 11, wherein some of the cross-drilled passages comprise intersecting straight holes that are machined from opposite lateral sides of the upper cooling plate.

13. The loadlock apparatus of claim 1, comprising an upper cooling plate assembly, comprising the upper cooling plate including cross-drilled passages, an inflow coupling member and an outflow coupling member coupled to the upper cooling plate and providing fluid communication with the cross-drilled passages, and a flexible conduit coupled to each of the inflow coupling member and an outflow coupling member.

14. A cooling plate assembly for a loadlock apparatus, comprising:
a cooling plate including cross-drilled passages, a distribution channel and a collection channel wherein each of the distribution channel and the collection channel intersects the cross-drilled passages;
an inflow coupling member and an outflow coupling member coupled to the cooling plate, the inflow coupling member including an entry channel and the outflow coupling member including an exit channel, the entry channel and the exit channels being interconnected to the cross-drilled passages by the distribution channel and the collection channel;
a flexible inflow conduit coupled to the inflow coupling member; and
a flexible outflow conduit coupled to the outflow coupling member.

15. An electronic device processing system, comprising:
a mainframe including a robot configured to move substrates;
a factory interface having one or more load ports; and
a loadlock apparatus received between the mainframe and the factory interface, the loadlock apparatus including:
a loadlock body including a lower loadlock chamber and an upper load loadlock chamber,
a lower cooling plate provided in the lower loadlock chamber,
an upper cooling plate provided in the upper loadlock chamber,
a lower disc diffuser centrally located above the lower cooling plate, and
an upper disc diffuser centrally located above the upper cooling plate.

16. A method of processing substrates, comprising:
providing a loadlock apparatus located between a mainframe and a factory interface, the loadlock apparatus including a loadlock body including a lower loadlock chamber and an upper load loadlock chamber, a lower cooling plate provided in the lower loadlock chamber, an upper cooling plate provided in the upper loadlock chamber, a lower disc diffuser centrally located above the lower cooling plate, and an upper disc diffuser centrally located above the upper cooling plate; and
flowing inert gas through the lower disc diffuser above the lower cooling plate.

17. The method of claim 16, comprising:
flowing inert gas through the upper disc diffuser above the upper cooling plate.

18. The method of claim 16, comprising:
cooling substrates in the upper loadlock chamber or the lower loadlock chamber.

19. The method of claim 18, wherein the cooling substrates comprises providing cooling liquid flow through cross-drilled passages in the upper cooling plate or the lower cooling plate.

20. The method of claim 16, comprising:
installing an upper cooling plate assembly to the loadlock body by inserting a flexible inflow conduit and a flexible outflow conduit into passageways formed horizontally in the loadlock body, and receiving an inflow coupling member and an outflow coupling member into cutouts formed in the loadlock body.
